(19) United States
(12) Patent Application Publication
(10) Pub. No.: US 2026/0164727 A1
(43) Pub. Date: Jun. 11, 2026

(54) NORMALLY OFF JFET

(71) Applicant: Microchip Technology Incorporated, Chandler, AZ (US)

(72) Inventors: Yogesh Kumar Sharma, Colorado Springs, CO (US); Shesh Mani Pandey, Gilbert, AZ (US)

(73) Assignee: Microchip Technology Incorporated, Chandler, AZ (US)

(21) Appl. No.: 19/179,715

(22) Filed: Apr. 15, 2025

Related U.S. Application Data
(60) Provisional application No. 63/703,350, filed on Oct. 4, 2024.

(51) Int. Cl. H10D 30/83; H10D 30/01; H10D 62/17; H10D 64/64; H10D 84/00

(52) U.S. Cl. CPC H10D 30/831; H10D 30/051; H10D 62/343; H10D 64/649; H10D 84/101

(57) ABSTRACT

A junction field-effect transistor that is normally off rather than normally on, and a method of making such a device. The junction field-effect transistor includes a volume of semiconductor material, a first gate located at a first side of the semiconductor material, a second gate located at a second side opposite and spaced apart from the first gate, a Schottky barrier diode, and a drain. The Schottky barrier diode is located at a first end of the semiconductor material between the first and second gates, and replaces a conventional source. The drain is located at the second end, opposite the diode, and a region of the semiconductor material between the diode and the drain provides a channel. The Schottky barrier diode conducts in a forward mode (i.e., the device is on) only when the anode-to-cathode voltage exceeds the metal-to-semiconductor barrier potential, which means the device is normally off.

### RELATED APPLICATION

The present U.S. non-provisional patent application is related to and claims priority benefit of an earlier-filed U.S. provisional patent application titled “Normally Off JFET,” Ser. No. 63/703,350, filed Oct. 4, 2024. The entire contents of the identified earlier-filed application is incorporated by reference as if fully set forth herein.

### FIELD

The present disclosure relates to junction field-effect transistors and methods of making them, and, more particularly, the various examples described herein concern a junction field-effect transistor that is normally off rather than normally on, and a method of making a junction field-effect transistor that is normally off rather than normally on.

### BACKGROUND

A junction field-effect transistor (JFET) is an active, voltage-controlled semiconductor device, in which varying an electrical voltage between a gate and a source controls an electrical current flowing through a semiconductor channel between a drain and the source. Applications for JFETs include amplifiers, switches, resistors, regulators, oscillators, and choppers. It is generally desirable to improve the performance and reduce the cost of JFETs, but it can be difficult to do so.

This background discussion is intended to provide related information, and is not necessarily prior art.

### SUMMARY

Examples provide a JFET that is normally off rather than normally on, and a method of making a JFET that is normally off rather than normally on. Broadly, a Schottky material serves as the source (essentially replacing the conventional source), which creates a Schottky barrier diode (SBD) at the junction of a Schottky material and a volume of semiconductor material. The Schottky material contacting the volume of semiconductor material forms the anode of the SBD, and a drain forms the cathode. The SBD conducts in forward mode (i.e., the JFET is on) only when the anode-to-cathode voltage exceeds the material-to-semiconductor barrier potential, which means the JFET is normally off. Examples advantageously improve the performance of the JFET and reduce the power loss.

In an example, a JFET that is normally off rather than normally on may include a volume of semiconductor material, a first gate, a second gate, an SBD, and a drain. The volume of semiconductor material may include a first end, a second end, a first side, and a second side. The first gate may be located at the first side of the volume of semiconductor material, and the second gate may be located at the second side and opposite and spaced apart from the first gate. The SBD may be located at the first end of the volume of semiconductor material between the first gate and the second gate, and the SBD may serve as a source and provide an entrance for a plurality of majority charge carriers. The drain may be spaced apart from the SBD and located at one of the ends of the volume of semiconductor material, and the drain may provide an exit for the majority charge carriers. A region of the volume of semiconductor material between the SBD and the drain may provide a channel through which the majority charge carriers move.

In another example, a JFET that is normally off rather than normally on may include a volume of semiconductor material, a first gate, a second gate, an SBD, and a drain. The volume of semiconductor material may include a first end, a second end, a first side, and a second side. The first gate may be located at the first side of the volume of semiconductor material, and the second gate may be located at the second side and opposite and spaced apart from the first gate. The SBD may be located at the first end of the volume of semiconductor material between the first gate and the second gate, and the SBD may provide an only entrance for a plurality of majority charge carriers. The drain may be spaced apart from the SBD and located at one of the ends of the volume of semiconductor material, and the drain may provide an exit for the majority charge carriers. A region of the volume of semiconductor material between the SBD and the drain may provide a channel through which the majority charge carriers move.

In another example, a method of forming a JFET that is normally off rather than normally on may comprising the following steps. A substrate, which will be the drain, is provided. A semiconductor material is grown on the substrate, wherein the semiconductor material will provide a channel. First and second lower gate components are implanted into respective first and second sides of the semiconductor material. First and second upper gate components are implanted into respective first and second sides of the semiconductor material, wherein the first upper gate component is more highly doped than the first lower gate component, and the second upper gate component is more highly doped than the second lower gate component. A Schottky metal is deposited on the semiconductor material at a first end of the channel opposite the drain and generally between and spaced apart from the upper components of the first and second gates. The following electrical terminals are provided for facilitating connections to appropriate voltage sources: a first electrical terminal on the Schottky metal, a second electrical terminal on the upper component of the first gate, a third electrical terminal on the upper component of the second gate, and a fourth electrical terminal on the drain.

Each of the preceding examples may further include any one or more of the following features. The volume of semiconductor material may include an N-type epitaxial semiconductor material, and the drain may include an N+ substrate material. The upper gate components may be a P++ material, and the lower gate components may be a P+ material. The SBD may include a Schottky material, which may be metal such as titanium, molybdenum, platinum, chromium, tungsten, aluminum, or combinations thereof. The first gate may include a lower first gate component partially extending into the volume of semiconductor material toward the second side of the volume of semiconductor material, and an upper first gate component located above the lower first gate component. The second gate may include a lower second gate component located opposite and spaced apart from the lower first gate component and partially extending into the volume of semiconductor material toward the first side of the volume of semiconductor material, such that a gap exists between the lower first gate component and the lower second gate component, and the channel extends through the gap, and an upper second gate component located above the lower second gate component and opposite and spaced apart from the upper second gate component. The upper first gate component may be more highly doped than the lower first gate component, and the upper second gate component may be more highly doped than the lower second gate component. The drain may be located at the second end of the volume of semiconductor material opposite from the Schottky barrier diode. The upper gate components may be symmetrical, and the lower gate components may be symmetrical. More particularly, the step of implanting the first and second lower gate components may include the steps of equally spacing the lower gate components from the first end of the semiconductor material and forming the lower gate components symmetrically. The step of implanting the first and second upper gate components may include the step of forming the upper gate components symmetrically. The steps of depositing the Schottky metal on the semiconductor material and providing the first electrical terminal on the Schottky metal may be performed as a single step, such that the first electrical terminal is formed of the Schottky metal.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of an example of a JFET that is normally off rather than normally on;

FIG. 2 is a flowchart of operations in an example of a method of making a JFET that is normally off rather than normally on;

FIG. 3A is a cross-sectional elevation view of the result of an operation in the method of FIG. 2, wherein a volume of N-type semiconductor material is provided on an N+ substrate, and first and second P+ structures are implanted;

FIG. 3B is a cross-sectional elevation view of the result of an operation in the method of FIG. 2, wherein first and second P++ structures are implanted;

FIG. 3C is a cross-sectional elevation view of the result of an operation in the method of FIG. 2, wherein an SBD material is deposited; and

FIG. 3D is a cross-sectional elevation view of the result of an operation in the method of FIG. 2, wherein electrical terminals are formed.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

JFETs are normally “on” (i.e., normally saturated) devices, and while they are fast, they are prone to power loss. Examples provide a JFET that is normally off rather than normally on, and a method of making a JFET that is normally off rather than normally on. Broadly, a Schottky material serves as the source (essentially replacing the conventional source), which creates an SBD at the junction of a Schottky material and a volume of semiconductor material. The Schottky material contacting the semiconductor material forms the anode of the SBD, and a drain forms the cathode. The SBD conducts in forward mode (i.e., the JFET is on) only when the anode-to-cathode voltage exceeds the material-to-semiconductor barrier potential, which means that the JFET is normally off. Examples advantageously provide improved performance and reduced power loss.

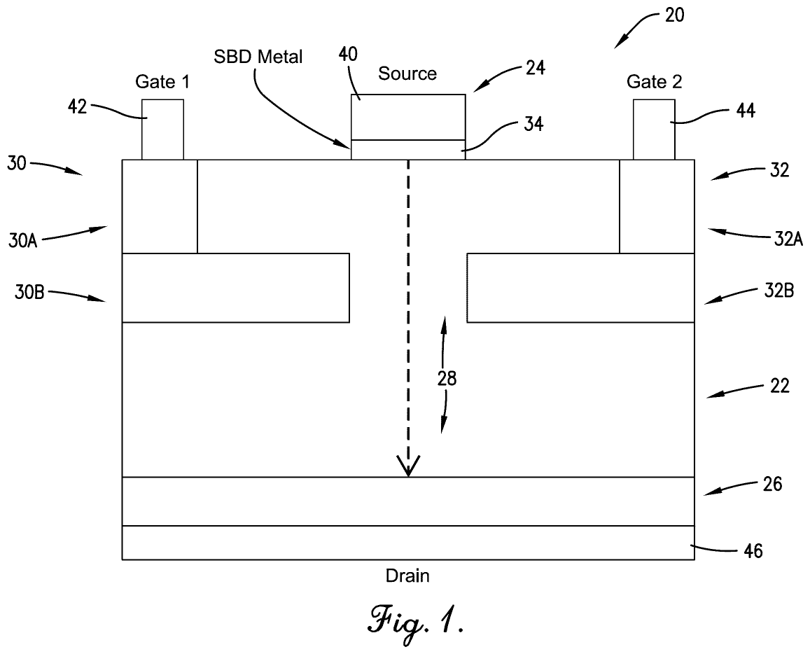

Referring to FIG. 1, an example of a JFET 20 that is normally off rather than normally on may include a volume of semiconductor material 22, an SBD 24, a drain 26, a channel 28, a first gate 30, and a second gate 32. The volume of semiconductor material 22 may include an N-type epitaxial semiconductor material and include a first end, a second end, a first side, and a second side.

It will be appreciated that the sides of the illustrated volume of semiconductor material are defined herein merely as an example, and may in various examples represent only a portion of semiconductor material relative to the illustrated JFET 20. In practice, the volume of semiconductor may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be FETs (which may be similarly or alternatively constructed to the JFET 20) or may be entirely different devices providing different operations or functions than the JFET 20. In other words, in practice, the illustrated JFET 20 may be just one of numerous devices spaced laterally and transversely within a single, integrally formed component, such as wafer (not shown).

The SBD 24 may be generally located at the first end and between the first and second sides of the volume of semiconductor material 22, where, conventionally, a source would be located, and provides an entrance for the majority charge carriers (e.g., electrons for N-channel). To be clear, there is no conventional source, the SBD 24 replaces the conventional source structure (which might typically include a structure of N+ material) and function as the entrance for the majority charge carriers. Thus, the SBD 24 may be the only entrance for the majority charge carriers. The SBD 24 may include a Schottky material 34, which may be a metal such as titanium, molybdenum, platinum, chromium, tungsten, aluminum, or combinations thereof.

The drain 26 may be located at the second end of the volume of semiconductor material 22, opposite and spaced apart from the SBD 22, and provide an exit for the majority charge carriers. In some examples, the drain may alternatively be located at the first end of the volume of semiconductor material to provide a lateral JFET construction. The drain 22 may be constructed from or include an N+ substrate material. The channel 28 may be a provided by a region of the volume of semiconductor material 22 between the SBD 24 and the drain 26 and through which the majority charge carriers move, i.e., through which electric current flows. It will be appreciated that the majority charge carriers, which are, in this case, electrons, flow from the SBD 24 to the drain 26, and the conventional current, Id, flows from the drain 26 to the SBD 24.

The first gate 30 may be generally located along the first side of the volume of semiconductor material 22, and may include an upper first gate component 30A and a lower first gate component 30B arranged in an approximately “L” shape. The upper first gate component 30A may be located at the first end of the volume of semiconductor material 22 and extend along the first side in the direction of the second end and the drain 26. The lower first gate component 30B may be located below the upper first gate component 30A and extend from the first side of the volume of semiconductor material 22 toward the second side. The upper first gate component 30A may be more highly doped than the lower first gate component 30B. The upper first gate component 30A may be constructed from or include an implanted P++ material, and the lower first gate component 30B may be constructed from or include an implanted P+ material.

The second gate 32 may be a mirror-image of the first gate 30 and generally located along the second side of the volume of semiconductor material 22, and may include an upper second gate component 32A and a lower second gate component 32B arranged in an approximately “reverse L” shape. The upper second gate component 32A may be located at the second end of the volume of semiconductor material 22 and extend along the second side in the direction of the second end and the drain 26. The lower second gate component 32B may be located below the upper second gate component 32A and extend from the second side of the volume of semiconductor material 22 toward the first side and the lower second gate component 30B. The upper second gate component 32A may be more highly doped than the lower second gate component 32B. The upper second gate component 32A may be constructed from or include an implanted P++ material, and the lower second gate component 32B may be constructed from or include an implanted P+ material. As seen in FIG. 1, the lower first and second gate components 30B, 32B may be separated by a gap of volume of semiconductor material generally located below the SBD 24 and between the SBD 24 and the drain 26. The channel 28 may extend from the SBD 24, through the gap between the lower first and second gate components 30B, 32B, to the drain 26.

In the JFET 20, the gates 30 and 32 are symmetric. However, according to some aspects of the illustrated example, gate asymmetry is permissible. For example, in some examples, the lower gates may be positioned at different depths within the volume of semiconductor material (e.g., the upper gate components may have different vertical lengths). Furthermore, in some examples, the upper gate components may not have the same shape and size, and/or the lower gate components may be dissimilarly sized and shaped relative to one another.

The SBD 24 may include a first electrical terminal 40, the first gate 30 may include a second electrical terminal 42, the second gate 32 may include a third electrical terminal 44, and the drain 26 may include a fourth electrical terminal 46 for facilitating connections to appropriate voltage sources.

In operation, an input voltage, Vds, may be applied across the first and fourth electrical terminals 40, 46 to cause electron drift/movement from the SBD 24 to the drain 26, and a control voltage, Vgs, may be applied across the first, second, and third electrical terminals 40, 42, 44 to control the width of the depletion region at the PN junctions where the charge carriers of the P-and N-type materials diffuse into each other, which “depletes” the available concentrations of majority charge carrier in each material, and thereby control the current, Id, from the drain 26 to the SBD 24. Thus, the SBD 24, the first gate 30, and the second gate 32 may cooperate under Vgs to control the current, Id, through the channel 28. If Vgs=0 V and Vds>0 V, electrons drift, or move, from the source to the drain, resulting in a current, Id, from the drain 26 to the SBD 24, and increased depletion regions at the PN junctions. If Vds=pinch-off voltage (Vp), then the depletion regions increase in size and grow sufficiently close to each other across the channel 28 that the current, Id, through the channel cannot increase and so is at its maximum, Id=(max drain current (Idss)). In the present examples, the SBD 24 conducts in forward mode (i.e., the JFET is on) only when the anode-to-cathode voltage exceeds the metal-to-semiconductor barrier potential, which means the JFET 20 is normally off.

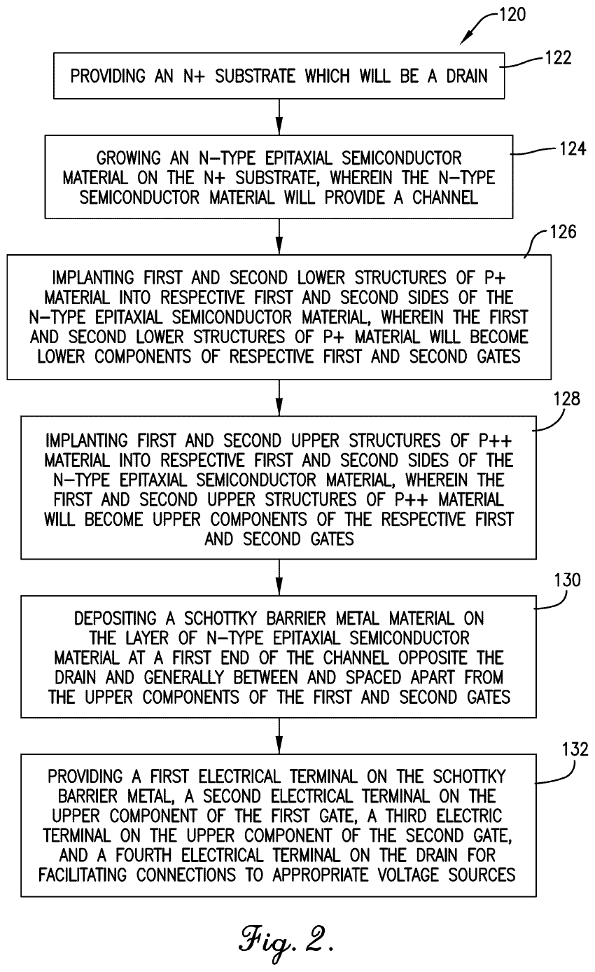

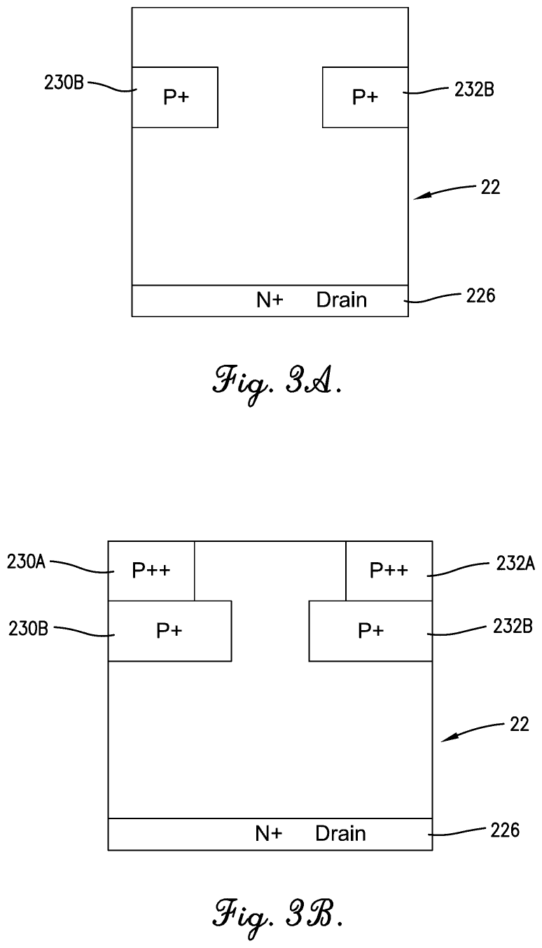

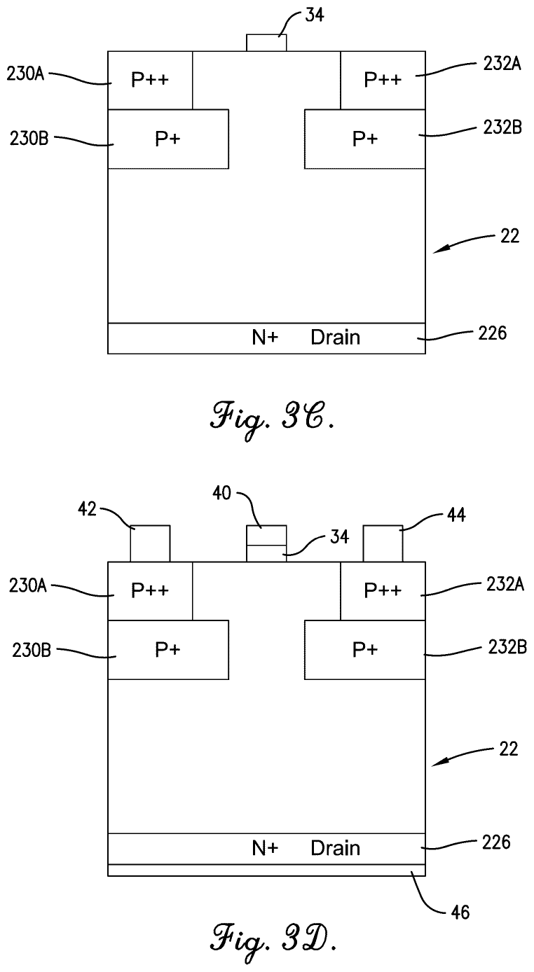

Referring to FIG. 2, an example of a method 120 of making a JFET that is normally off rather than normally on, such as the example JFET 20 of FIG. 1, may include the operations set forth below. Referring additionally to FIGS. 3A-D, example results are shown of various operations of the method 120, which may be stages in the production of the JFET 20.

An N+ substrate 226 may be provided, as shown in 122 and seen in FIG. 3A. The N+ substrate may provide the drain 26. The N+ substrate may be a 4H-SiC material. The volume of semiconductor material 22 may be grown or otherwise provided on the N+ substrate 226, as shown in 124 and also seen in FIG. 3A. The volume of semiconductor material 22 may include a first end, a second end, a first side, and a second side, with the N+ substrate 226 being located at the second end. (As noted above, according to some aspects, although a substrate may still underly the volume of semiconductor material, the N+ drain may alternatively be provided at the first end of the semiconductor material.) The volume of semiconductor material 22 may be an N-type epitaxial semiconductor material.

First and second lower structures of P+ material 230B, 232B, which may become the lower components 30B, 32B of the respective first and second gates 30, 32 may be implanted or otherwise provided at the first and second sides, respectively, of the volume of semiconductor material 22, as shown in 126 and also seen in FIG. 3A. First and second upper structures of P++ material 230A, 232A, which may become the upper components 30A, 32A of the respective first and second gates 30, 32, may be implanted or otherwise provided in or on the first and second sides, respectively, of the volume of semiconductor material 22 above the respective first and second lower structures of P+ material 230B, 232B, as shown in 128 and seen in FIG. 3B.

In more detail, the first lower and upper structures of P+ and P++ materials 230B, 230A, which, together, may form the first gate 30, may be arranged in an approximately “L” shape. The first upper structure 230A may be located at the first end of the volume of semiconductor material 22 and extend along the first side in the direction of the second end. The first lower structure 230B may be located below the first upper structure 230A and extend from the first side of the volume of semiconductor material 22 toward the second side of the volume of semiconductor material 22. The second lower and upper structures of P+ and P++ materials 232B, 232A, which, together, may form the second gate 32, may be arranged in an approximately “reverse L” shape, i.e., as a mirror image of the first gate 30. The first upper structure 232A may be located at the first end of the volume of semiconductor material 22 and extend along the second side in the direction of the second end. The second lower structure 232B may be located below the second upper structure 232A and extend from the second side of the volume of semiconductor material 22 toward the first side of the volume of semiconductor material 22. The lower first and second structures 230B, 232B may be separated by a gap of semiconductor material generally located below the SBD material 34 and between the SBD 24 and the N+ substrate 226 of the drain 26. The channel 28 may extend from the SBD 24, through the gap between the lower first and second structures 230B, 232B of the first and second gate 30, 32, to the N+ substrate 226 of the drain 26. According to some aspects of the illustrated example, the first and second lower structures 230B and 232B may alternatively be implanted at different depths within the volume of semiconductor material (such that the first and second upper structures 230A and 232A present different vertical lengths). As previously noted, additional alternative examples may also encompass upper structures having different shapes and sizes and lower structures having different shapes and sizes.

As shown in 130 and seen in FIG. 3C, the Schottky material 34, which may be part of the SBD 24, may be deposited or otherwise provided on the first end of the volume of semiconductor material 22. The Schottky material 34 may be spaced apart from and opposite the N+ substrate 226 and generally between and spaced apart from the first and second upper P++ structures 230A, 232A of the first and second gates 30, 32 and the first and second sides of the volume of volume of semiconductor material 22 where, conventionally, a source would be located. To be clear, there is no conventional source, the SBD 24 serves as the source structure (which might typically include an N+ material) and function as the entrance for the majority charge carriers. Thus, the SBD 24 may be the only entrance for the majority charge carriers. The Schottky material 34 may be a metal such as titanium, molybdenum, platinum, chromium, tungsten, aluminum, or combinations thereof.

The first electrical terminal 40 may be provided on the SBD material 34, the second electrical terminal 42 may be provided on structure of P++ material 230A of the upper component 30A of the first gate 30, the third electrical terminal 44 may be provided on the structure of P++ material 232A of the upper component 32A of the second gate 32, and the fourth electrical terminal 46 may be provided on the N+ substrate 226 of the drain 26, as shown in 132 and seen in FIG. 3D, for facilitating connections to appropriate voltage sources. According to some aspects of the illustrated embodiment, the first electrical terminal 40 may be formed of Schottky metal, such that the steps of depositing the Schottky metal 34 on the semiconductor material and providing the first electrical terminal 40 on the Schottky metal 34 are integrated (or performed simultaneously). In this alternative, the first electrical terminal and the Schottky metal are one and the same.

Additional processing may occur as desired.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 1×10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A junction field-effect transistor that is normally off rather than normally on, the junction field-effect transistor comprising:
a volume of semiconductor material including a first end, a second end, a first side, and a second side;
a first gate located at the first side of the volume of semiconductor material;
a second gate located at the second side of the volume of semiconductor material, wherein the second gate is opposite and spaced apart from the first gate;
a Schottky barrier diode located at the first end of the volume of semiconductor material between the first gate and the second gate, wherein the Schottky barrier diode serves as a source and provides an entrance for a plurality of majority charge carriers; and
a drain spaced apart from the Schottky barrier diode and located at one of the ends of the volume of semiconductor material, wherein the drain provides an exit for the plurality of majority charge carriers, and wherein a region of the volume of semiconductor material between the Schottky barrier diode and the drain provides a channel through which the plurality of majority charge carriers move.

2. The junction field-effect transistor of claim 1, wherein - the volume of semiconductor material includes an N-type epitaxial semiconductor material; and
the drain includes an N+ substrate material.

3. The junction field-effect transistor of claim 1, wherein the Schottky barrier diode includes a Schottky material selected from the group consisting of: titanium, molybdenum, platinum, chromium, tungsten, aluminum, and combinations thereof.

4. The junction field-effect transistor of claim 1, wherein the drain is located at the second end of the volume of semiconductor material opposite from the Schottky barrier diode.

5. The junction field-effect transistor of claim 4, wherein the the first gate includes
a lower first gate component partially extending into the volume of semiconductor material toward the second side of the volume of semiconductor material, and
an upper first gate component located above the lower first gate component; and the second gate includes
a lower second gate component located opposite and spaced apart from the lower first gate component and partially extending into the volume of semiconductor material toward the first side of the volume of semiconductor material, such that a gap exists between the lower first gate component and the lower second gate component, and the channel extends through the gap, and
an upper second gate component located above the lower second gate component and opposite and spaced apart from the upper second gate component.

6. The junction field-effect transistor of claim 5, wherein the upper gate components are symmetrical and the lower gate components are symmetrical.

7. The junction field-effect transistor of claim 5, wherein the upper first gate component is more highly doped than the lower first gate component, and the upper second gate component is more highly doped than the lower second gate component.

8. A junction field-effect transistor that is normally off rather than normally on, the junction field-effect transistor comprising:
a volume of semiconductor material including a first end, a second end, a first side, and a second side;
a first gate located at the first side of the volume of semiconductor material;
a second gate located at the second side of the volume of semiconductor material, wherein the second gate is opposite and spaced apart from the first gate;
a Schottky barrier diode located at the first end of the volume of semiconductor material between the first gate and the second gate, wherein the Schottky barrier diode provides an only entrance for a plurality of majority charge carriers; and
a drain spaced apart from the Schottky barrier diode and located at one of the ends of the volume of semiconductor material, wherein the drain provides an exit for the plurality of majority charge carriers, and wherein a region of the volume of semiconductor material between the Schottky barrier diode and the drain provides a channel through which the plurality of majority charge carriers move.

9. The junction field-effect transistor of claim 8, wherein the volume of semiconductor material includes an N-type epitaxial semiconductor material; and the drain includes an N+ substrate material.

10. The junction field-effect transistor of claim 8, wherein the Schottky barrier diode includes a Schottky material selected from the group consisting of: titanium, molybdenum, platinum, chromium, tungsten, aluminum, and combinations thereof.

11. The junction field-effect transistor of claim 8, wherein the drain is located at the second end of the volume of semiconductor material opposite from the Schottky barrier diode.

12. The junction field-effect transistor of claim 11, wherein the the first gate includes
a lower first gate component partially extending into the volume of semiconductor material toward the second side of the volume of semiconductor material, and
an upper first gate component located above the lower first gate component; and the second gate includes
a lower second gate component located opposite and spaced apart from the lower first gate component and partially extending into the volume of semiconductor material toward the first side of the volume of semiconductor material, such that a gap exists between the lower first gate component and the lower second gate component, and the channel extends through the gap, and
an upper second gate component located above the lower second gate component and opposite and spaced apart from the upper second gate component.

13. The junction field-effect transistor of claim 12, wherein the upper gate components are symmetrical and the lower gate components are symmetrical.

14. The junction field-effect transistor of claim 13, wherein the upper first gate component is more highly doped than the lower first gate component, and the upper second gate component is more highly doped than the lower second gate component.

15. A method of making a junction field-effect transistor that is normally off rather than normally on, the method comprising:
providing a substrate which will be the drain;
growing a semiconductor material on the substrate, wherein the semiconductor material will provide a channel;
implanting first and second lower gate components into respective first and second sides of the semiconductor material;
implanting first and second upper gate components into respective first and second sides of the semiconductor material, wherein the first upper gate component is more highly doped than the first lower gate component, and the second upper gate component is more highly doped than the second lower gate component;
depositing a Schottky metal on the semiconductor material at a first end of the channel opposite the drain and generally between and spaced apart from the upper components of the first and second gates; and
providing a first electrical terminal on the Schottky metal, a second electrical terminal on the upper component of the first gate, a third electrical terminal on the upper component of the second gate, and a fourth electrical terminal on the drain for facilitating connections to appropriate voltage sources.

16. The method of making a junction field-effect transistor of claim 15, wherein the substrate is an N+ material and the step of growing the semiconductor material includes epitaxially growing N-type material.

17. The method of making a junction field-effect transistor of claim 16, wherein the upper gate components are a P++ material, the lower gate components are a P+ material, and the Schottky metal is selected from the group consisting of: titanium, molybdenum, platinum, chromium, tungsten, aluminum, and combinations thereof.

18. The method of making a junction field-effect transistor of claim 15, wherein the step of implanting the first and second lower gate components includes the steps of equally spacing the lower gate components from the first end of the semiconductor material and forming the lower gate components symmetrically.

19. The method of making a junction field-effect transistor of claim 18, wherein the step of implanting the first and second upper gate components includes the step of forming the upper gate components symmetrically.

20. The method making a junction field-effect transistor of claim 15, wherein the steps of depositing the Schottky metal on the semiconductor material and providing the first electrical terminal on the Schottky metal are performed as a single step, such that the first electrical terminal is formed of the Schottky metal.
